(19) United States
(12) Patent Application Publication
(10) Pub. No.: US 2004/0232312 A1
(43) Pub. Date: Nov. 25, 2004

(54) Image generation device and method for producing such an image generation device

(76) Inventor: Horst Belau, Langquaid (DE)

Correspondence Address: MORRISON & FOERSTER LLP, 1650 TYSONS BOULEVARD, SUITE 300, MCLEAN, VA, 22102, US

(21) Appl. No.: 10/479,082

(22) PCT Filed: Jul. 16, 2001
(86) PCT No.: PCT/DE01/02654

(30) Foreign Application Priority Data
Jun. 29, 2001 (DE) 101 31605.4

(51) Int. Cl. H01L 27/00

(52) U.S. Cl. 250/208.1

(57) ABSTRACT

The invention relates to an image generation device, especially a 3D camera, comprising at least one picture-recording sensor (10) disposed on a printed board (12). The inventive device is specifically characterized in that the picture-recording sensor (10) is configured by a bare integrated circuit disposed on a printed board (12). The invention further relates to a method for producing such an image generation device.

The present invention relates to an image generating device, in particular a 3D camera, having at least one image recording sensor which is arranged on a printed board. The present invention additionally relates to a method for manufacturing an image generating device, in particular the image generating device as claimed in the invention, wherein the (finished) image generating device includes a printed board on which at least one image recording sensor and at least one further component are arranged.

The image generating devices of the type in question can be utilized inter alia in conjunction with motor vehicle engineering; in order to determine the position of objects within a scene, for example, as described in WO 00/65538. The image recording sensors in the prior art are normally supplied in an encapsulated casing. The mounting onto the printed board of such image recording sensors, which are housed in an encapsulated casing, is normally performed in much the same way as the mounting of ICs having corresponding casings. In the case of image recording sensors, however, at least some sections of the casing must have optical properties which allow the operation of the sensor that is housed in the casing. The use of image recording sensors which are supplied in encapsulated casings is therefore relatively expensive.

The object of the invention is therefore to develop the image generating devices of the type in question and the manufacturing method of the type in question, such that the manufacturing costs can be reduced.

This object is achieved by the features specified in the independent claims.

Advantageous configurations and developments of the invention are specified in the dependent claims.

The claimed image generating device is based on the prior art of the type in question, in that the image recording sensor is formed by a bare integrated circuit which is arranged on a printed board. In connection with the present invention, a “bare integrated circuit” is understood to mean a semiconductor chip (die) which is designed to be mounted without an IC casing on a printed board. The use of such an image recording sensor makes it possible to dispense with costly optical IC casings, and a mechanical separation of printed board and a camera casing, for example, becomes possible.

In connection with the claimed image generating device, it is considered particularly advantageous if provision is made for the image recording sensor to be formed by a CMOS sensor (CMOS=Complementary Metal Oxide Semiconductor). Although other sensor types such as CCD sensors (CCD=Charge Coupled Device) can also be considered in principle, the use of a CMOS sensor offers several advantages. A CMOS sensor normally has a lower power consumption that a CCD sensor, for example. Since charges do not have to be transported over light-sensitive sensor surfaces in the case of CMOS sensors, the so-called smear effect does not occur, said smear effect being considered extremely disadvantageous. Furthermore, unrestricted pixel access is normally possible in the case of CMOS sensors. By contrast, it is normally only possible to read out individual lines in the case of CCD sensors.

In a particularly preferred embodiment of the claimed image generating device, provision is additionally made for arranging the image recording sensor on the printed board by means of flip-chip technology. In the case of flip-chip technology, the pads of a silicon chip are provided with a solderable metal bump (solder bump). The chips which are prepared in this way can be arranged with their active side (face down) on a substrate having corresponding pads and simultaneously bonded by a reflow process. In comparison with wire-bond technology, for example, flip-chip technology has the following advantages in particular. A greater number of connections is possible, fewer parasitic effects occur, and less space is required. After the bonding, the underside of the image recording sensor is preferably covered with a plastic material.

Particularly if flip-chip technology is used, provision is additionally made, in the case of the claimed image generating device, for the active area of the image recording sensor, of which there is at least one, to be arranged opposite an opening which is provided in the printed board. In this case, the dimensions of the opening are preferably adapted to the dimensions of the active area of the image recording sensor.

In some embodiments of the claimed image generating device, it is advantageous if provision is made at least partially to cover the opening by means of a cover element on the printed board side which is opposite to the image recording sensor. The cover element can be made of glass, for example, but is not restricted to being made of glass.

In connection with the above, provision can also be made in the case of the claimed image generating device for the cover element to have filtering properties. In this case, the cover element can be part of an optics system which is described in greater detail below.

A preferred development of the claimed image generating device provides for including an optics system which interacts with the image recording sensor. In particular, this optics system can comprise one or more lenses, apertures and the like. If a cover element as mentioned above is used, this can also be part of the optics system.

If the claimed image generating device has an optics system, provision is preferably made for said optics system to be a preadjusted unit, which is aligned in relation to the image recording sensor, using a printed board surface as a reference plane. This solution offers the advantage that, following a relatively straightforward installation of the optics system, no further adjustment is required.

In connection with the above, the claimed image generating device is preferably developed such that the optics system is arranged on the printed board side which is opposite to the image recording sensor. In this case, the printed board side which is facing the image recording sensor, for example, can form the aforementioned reference plane.

If the image generating device has an optics system, it is advantageous in many cases to provide for the optics system to include an optics system casing which is arranged in the area of the opening on the printed board. In this case, a lens which forms or is part of the optics system can be inserted in an opening in the optics system casing. If the optics system casing is adequately sealed in relation to the printed board, such that contamination of the active part of the image recording sensor can be reliably prevented, it is possible in many cases to dispense with the aforementioned cover element for covering the opening in the printed board.

In this connection, a preferred development of the claimed image generating device provides for the optics system casing to be fastened to the printed board using fastening means. For this purpose, the optics system casing can be extended to include a type of collar, for example, on its perimeter area facing the printed board, and the collar can have holes, which align with holes provided in the printed board, through which bolts or similar means can therefore be guided for fastening the optics system casing. Such bolts can be fastened by a soldered joint, for example.

In some embodiments of the claimed image generating device, it is considered advantageous if provision is made for the printed board to include a protective layer in the area of the opening. Such a protective layer can be formed by a metallized layer, for example, which serves as protection against humidity.

In specific applications areas of the claimed image generating device, provision is additionally made for it to include a further image recording sensor. Depending on the alignment of the active area of the further image recording sensor, it is possible to form a 3D camera, for example, in this way. In this case, the further image recording sensor is preferably of the same type as the image recording sensor which is provided in each case, and is preferably installed in the same way.

In the case of the claimed image generating device, provision can additionally be made to arrange the printed board in a casing having at least one optical window. If more than one image recording sensor is provided, the casing either has a separate optical window for each image recording sensor or one correspondingly larger optical window. The optical window or windows are preferably transparent to infrared radiation, in particular in order to allow nighttime recordings.

The method of the type in question for manufacturing an image generating device is based on the prior art of the type in question, in that it includes the following steps:

a) assembling the printed board with the further component, of which there is at least one,

b) introducing the printed board, on which at least one further component is assembled, into a clean room,

c) installing the image recording sensor in the clean room.

The claimed method ensures that the image recording sensor is not affected by the comparatively unfavorable conditions of the printed board production in respect of contamination and thermal stress. Therefore sensitive image recording sensors can also be used, in particular image recording sensors which do not have their own casing.

In a preferred embodiment of the claimed method, provision is made, when executing the method step a), at least partially to cover the area which is provided for the installation of the image recording sensor. This measure is intended to prevent any possible contamination of the area which is provided for the installation of the image recording sensor, when assembling the component or components on the printed board.

In a particularly preferred embodiment of the claimed method, provision is made for a bare integrated circuit to form the image recording sensor which is installed when executing the method step c). In connection with the claimed method, “bare integrated circuit” is again understood to mean a semiconductor chip (die) which is designed to be installed without an IC casing on a printed board. As mentioned above, the use of such an image recording sensor makes it possible to dispense with costly optical IC casings and a mechanical separation of printed board and a camera casing, for example, becomes possible.

In connection with the above in particular, the claimed method preferably provides for the use of flip-flop technology when executing the method step c). The installation of the image recording sensor by means of flip-flop technology preferably includes the underside of the image recording sensor being covered with a plastic material after the bonding. In order to avoid repetition in relation to the attributes of flip-flop technology and the potential advantages thereof, reference is made to the corresponding explanations given in connection with the claimed image generating device.

In a preferred embodiment of the claimed method, when executing the method step c), provision is made for an active area of the image recording sensor to be arranged relative to an opening which is provided in the printed board. Again in this case, the dimensions of the opening are preferably adapted to the dimensions of the active area of the image recording sensor.

In connection with the above in particular, provision can be made for the following further step in the claimed method:

d) covering the opening, on the printed board side which is opposite to the image recording sensor, by means of a cover element.

Also in connection with the claimed method, the cover element can be made of glass, for example, but is not restricted to being made of glass.

In this connection, a development of the claimed method can provide for the cover element used in method step d) to have filtering properties. Additionally or alternatively, it is also conceivable for the cover element to be formed by a lens.

As in the case of the claimed image generating device, the cover element can again be part of an optics system which interacts with the image recording sensor.

The claimed method preferably includes the following further step:

e) installing, in the clean room, an optics system which interacts with the image recording sensor.

This additional step is particularly advantageous if the optics system has an optics system casing or forms part of a casing which protects at least the active area of the image recording sensor from contamination. Such an optics system casing, together with the optics system, can be fastened to the printed board in the same way, for example, as described above in connection with the claimed image generating device. In particular, the optics system can again comprise one or more lenses, apertures and the like in connection with the claimed method. If a cover element as mentioned above is used, this can also be part of the optics system. However, consideration is also given to embodiments in which it is possible to dispense with the cover element because the optics system casing already adequately protects the active area of the image recording sensor, particularly against contamination.

In connection with an optics system which interacts with the image recording sensor, the claimed method preferably provides for the optics system to be aligned in relation to the image recording sensor when executing the method step e), by using a printed board surface as a reference plane. The reference plane is the same plane as that which is also formed by the sensor surface. In this way, it is possible to dispense with subsequent adjustment operations in most cases, thereby contributing to a reduction in costs.

If an optics system is installed, the claimed method preferably provides for the optics system to be arranged on the printed board side which is opposite to the image recording sensor when executing the method step e). In this case, the printed board side which is facing the image recording sensor, for example, can form the aforementioned reference plane, as described above in connection with the claimed image generating device.

In the case of specific embodiments, the claimed method includes the following further step:

f) introducing the assembled printed board into a casing.

The casing preferably has at least one optical window, which is located opposite the active area of the image recording sensor or the optics system following the introduction of the assembled printed board. If more than one image recording sensor is provided, the casing either has a separate optical window for each image recording sensor or one correspondingly larger optical window. The optical window or windows are preferably transparent to infrared radiation, in particular in order to allow nighttime recordings, as previously described in connection with the claimed image generating device.

The invention is subsequently described in greater detail with reference to exemplary embodiments shown in the drawings, in which:

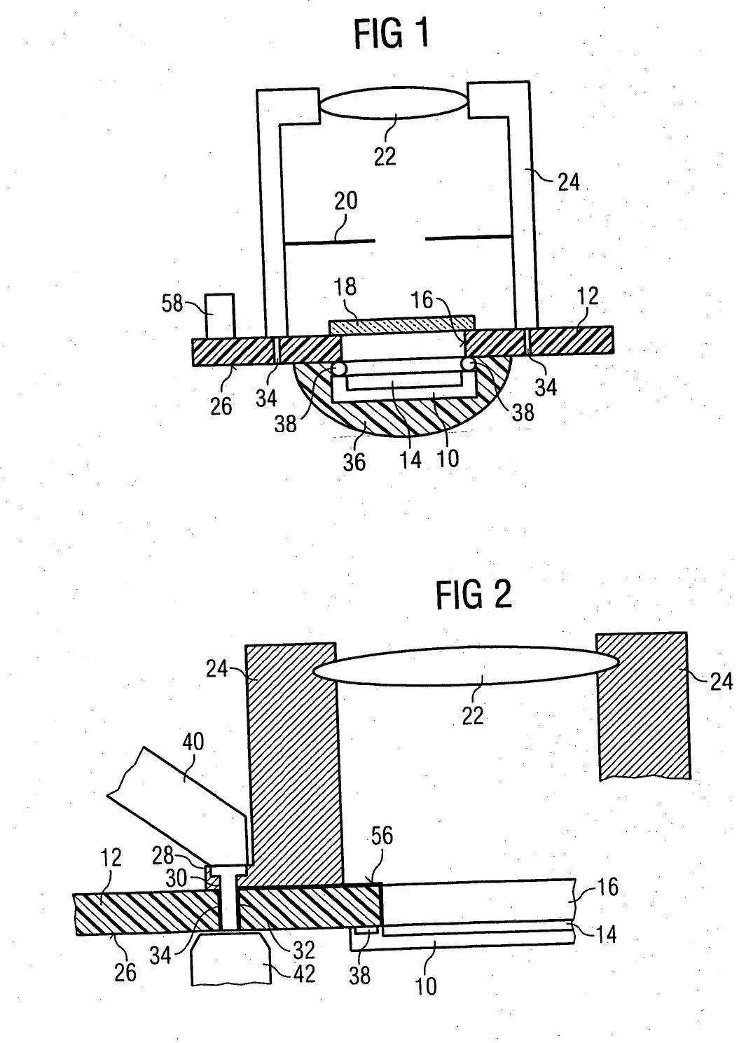

FIG. 1 shows a schematic sectional view of a first embodiment of the claimed image generating device,

FIG. 2 shows a schematic sectional view of a second embodiment of the claimed image generating device during execution of the claimed method, and

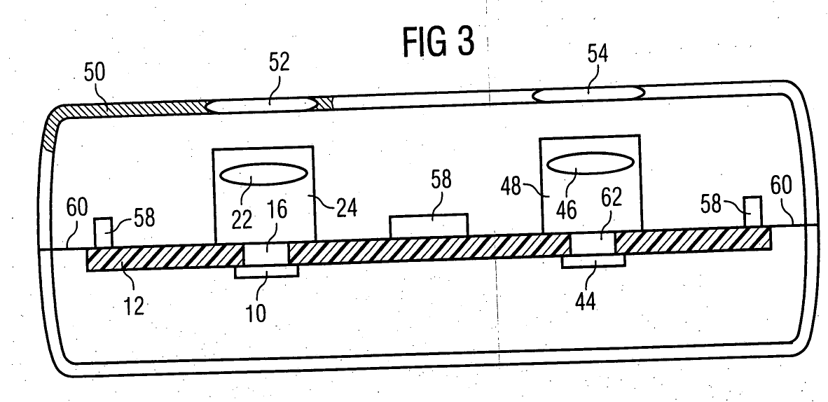

FIG. 3 shows a schematic sectional view of a third embodiment of the claimed image generating device.

The embodiment of the claimed image generating device shown in FIG. 1 includes a printed board 12, which has an opening 16 that can be circular, for example. An image recording sensor 10 which can be a CMOS sensor, in particular, is arranged relative to the opening 16. The image recording sensor 10 is fastened to the printed board 12 by means of flip-chip technology and is connected by means of flip-chip solder 38 to the connection pad (not shown in FIG. 1) of the printed board 12. The image recording sensor 10 has an active area 14, wherein the dimensions of the opening 16 in the printed board 12 are adapted to the dimensions of the active area 14 of the image recording sensor 10. With reference to the illustration in FIG. 1, the lower side of the image recording sensor 10 is covered with plastic material (glop top). A cover element 18 is provided on the printed board 12 side which is opposite the image recording sensor 10, wherein said cover element can be made of glass, for example, and can have filtering properties. An optics system casing 24 is likewise arranged on the printed board 12 side which is opposite the image recording sensor 10, wherein said optics system casing holds an aperture 20 and a lens system 22. The aperture 20, the lens system 22 and, if applicable, the cover element 18 jointly form an optics system which interacts with the active area 14 of the image recording sensor 10. The cover element 18 is preferably transparent to infrared radiation, and the distance between the cover element 18 and the active area 14 of the image recording sensor 10 ensures that any dust particles that may be present on the cover element 18 do not have a significantly negative effect on the imaging properties. It is possible to dispense with the cover element 18, if appropriate, particularly if the optics system casing 24 seals the active area 14 of the image recording sensor 10 against the environment. In the embodiment of the claimed image generating device as shown in FIG. 1, the aperture 20, the lens system 22 and the optical housing 24 jointly form a preadjusted unit, wherein the lower side of the board 12 as illustrated in FIG. 1 is used as a reference plane 34 during installation. Consequently, no further adjustment operations are required following installation.

For manufacturing the embodiment of the claimed image generating device as illustrated in FIG. 1, the claimed method can be carried out as follows, for example. Firstly, at least one component is assembled on the printed board 12 during manufacture of the printed board, though normally a plurality of further elements are assembled in practice, only one further component 58 being indicated. During assembly of the printed board 12 with the further components 58, the area which is provided for the installation of the image recording sensor 10 (and preferably the area provided for the installation of the optics system 20, 22, 24) is covered, in order to protect this area or areas against contamination. After all the components except for the image recording sensor 10, the cover element 18 and the optics system casing 24 including the aperture 20 and the lens system 22 have been arranged on the printed board, the thus assembled printed board 12 undergoes hybrid manufacturing and is introduced into a clean room for this purpose. The installation resumes in the clean room. Firstly, the image recording sensor 10 is arranged by means of flip-chip technology into the position shown in FIG. 1. The underside of the image recording sensor 10 is then covered with a plastic material 36. The opening 16 in the printed board 12 is covered, by means of a cover element 18, on its board 12 side which is opposite to the image recording sensor 10. The preadjusted optical unit is then installed, including the optics system casing 24, the aperture 20 and the lens system 22. In this case, the lower side of the printed board 12 as shown in FIG. 1 is used as a reference plane 26. A possible fastening variant for the optics system casing 24 is explained below in greater detail with reference to the illustration in FIG. 2.

FIG. 2 shows a schematic sectional view of a second embodiment of the claimed image generating device during the execution of the claimed method. With reference to the illustration in FIG. 2, an image recording sensor 10 having an active area 14 is arranged beneath an opening 16 by means of flip-chip technology, said opening being provided in a printed board 12. The reference numeral 38 again indicates flip-chip solder. A protective layer 56 is provided in the area of the opening 16, said protective layer being, for example, a metallized layer for protecting against humidity. In the embodiment illustrated in FIG. 2, no cover element is provided for the opening 16, and the optics system comprises merely a lens system 22 which is held by an optics system casing 24. The optics system casing 24 has a collar 28 for connecting to the printed board 12, said collar being provided in the lower terminating section of the optics system casing 24 with reference to the illustration in FIG. 2. The collar 28 has a hole 30 which aligns with a hole 32 that is provided in the printed board 12. A bolt 34 is guided through the holes 30, 32, and fastened to the printed board 12 by means of a soldered joint. For this purpose, for example, a soldering iron 40 which is indicated only schematically in FIG. 2 can interact with a suitable tool backing-support 42, while the optics system casing with the lens system 22 is installed in a clean room.

FIG. 3 shows a schematic sectional view of a third embodiment of the claimed image generating device. In the embodiment of the claimed image generating device as illustrated in FIG. 3, a printed board 12 has an opening 16 and a further opening 62. An image recording sensor 10 is arranged adjacently to the opening 16, while a further image recording sensor 44 is provided adjacently to the further opening 62. The type and the arrangement of the image recording sensors 10, 44 can correspond to the embodiments as illustrated in FIG. 1 or 2. An optics system casing 24 is assigned to the image recording sensor 10 and holds a lens system 22. Similarly, a further optics system casing 48 is assigned to the further image recording sensor 44 and holds a further lens system 46. The installation of the image recording sensors 10, 44 together with the optics system casings 24, 48 and associated lens systems 22, 46 was carried out in a clean room, while further components 58 were arranged during the normal manufacture of the printed board. The board 12 is arranged within a casing 50 by means of mountings 60, such that the printed board 12 together with the image recording sensors 10, 44, the optics system casings 24, 48, and the lens systems 22, 46, is mechanically separated from the casing 50. The printed board 12, together with the components arranged thereupon, is consequently well protected against external influences. The casing 50 has an optical window 52 which is assigned to the image recording sensor 10, and a further optical window 54 which is assigned to the image recording sensor 44, wherein the overall arrangement is such that radiation passing through the optical windows 52, 54 reaches the active areas of the image recording sensors 10, 44. The optical windows 52, 54 are made from a material which is transparent to infrared radiation, so that nighttime recordings are possible, for example. Environmental influences such as humidity or temperature fluctuations, for example, can be addressed by means of a suitable board structure.

The features of the invention which are disclosed in the foregoing description, in the drawings and in the claims, can be essential both individually and in any combination for reducing the invention to practice.

1. An image generating device, in particular a 3D camera, having at least one image recording sensor (10) which is arranged on a printed board (12), wherein
the image recording sensor (10) is formed by a bare integrated circuit which is arranged on a printed board (12), and wherein
the image recording sensor (10) interacts with an optics system (20, 22),
characterized in that
the optics system (20, 22) is a preadjusted unit which is aligned in relation to the image recording sensor (10) using a printed board surface as a reference plane (26).

2. The image generating device as claimed in claim 1,
characterized in that the image recording sensor (10) is formed by a CMOS sensor.

3. The image generating device as claimed in claim 1 or 2,
characterized in that the image recording sensor (10) is arranged on the printed board (12) by means of flip-chip technology.

4. The image generating device as claimed in one of the preceding claims,
characterized in that an active area (14) of the image recording sensor (10), of which there is at least one, is arranged opposite an opening (16) which is provided in the printed board (12).

5. The image generating device as claimed in claim 4,
characterized in that the opening (16) is at least partially covered by a cover element (18) on the printed board (12) side which is opposite to the image recording sensor (10).

6. The image generating device as claimed in claim 4 or 5,
characterized in that the cover element (18) has filtering properties.

7. The image generating device as claimed in claim 6,
characterized in that the optics system (20, 22) is arranged on the printed board (12) side which is opposite to the image recording sensor (10).

8. The image generating device as claimed in one of claims 6 or 7,
characterized in that the optics system (20, 22) has an optics system casing (24) which is arranged in the area of the opening (16) on the printed board (12).

9. The image generating device as claimed in claim 8,
characterized in that the optics system casing (24) is fastened to the printed board (12) using fastening means (28, 30, 32, 34).

10. The image generating device as claimed in one of claims 4 to 9,
characterized in that the printed board (12) has a protective layer (56) in the area of the opening (16).

11. The image generating device as claimed in one of the preceding claims,
characterized in that it has a further image recording sensor (44).

12. The image generating device as claimed in one of the preceding claims,
characterized in that the printed board (12) is arranged in a casing (50) having at least one optical window (52, 54).
